(19) United States
(12) Patent Application Publication
(10) Pub. No.: US 2017/0062317 A1
(43) Pub. Date: Mar. 2, 2017

(54) POWER SEMICONDUCTOR MODULE AND METHOD FOR MANUFACTURING THE SAME

(71) Applicants: Hyundai Motor Company, Seoul (KR); Infineon Technologies AG, Neubiberg (DE); Kia Motors Corporation, Seoul (KR)

(72) Inventors: Jeong-Min Son, Seongnam (KR); Andreas Grassmann, Regensburg (DE)

(21) Appl. No.: 14/954,093

(22) Filed: Nov. 30, 2015

(30) Foreign Application Priority Data
Aug. 25, 2015 (KR) 10-2015-0119280

(51) Int. Cl. H01L 23/495; H01L 23/367; H01L 25/07; H01L 21/52

(52) U.S. Cl. CPC H01L 23/49575; H01L 23/49541; H01L 21/52; H01L 23/3675; H01L 25/071; H01L 2021/60277

(57) ABSTRACT

A power semiconductor module is provided. The power semiconductor module includes a lower substrate and a first electronic device bonded to a surface of the lower substrate. A lead frame has a first side surface bonded to a surface of the first electronic device by a first adhesive, and a second electronic device bonded to a second side surface of the lead frame by the first adhesive. An upper substrate is bonded to a surface of the second electronic device.

### CROSS-REFERENCE(S) TO RELATED APPLICATIONS

This application claims priority to Korean Patent Application No(s). 10-2015-0119280 filed on Aug. 25, 2015, which is incorporated herein by reference in its entirety.

### BACKGROUND

Field of the Invention

The present invention relates to a power module, and more particularly, to a power module that directly bonds electronic device and a lead and a method for manufacturing the same.

Description of Related Art

Recently, the competition to develop an eco-friendly vehicle, has initiated research and development to improve the performance of a power module which is one of the core parts of the eco-friendly vehicle. In particular, improvement in cooling efficiency of a power semiconductor module that generates a considerable amount of heat and/or reduction in a volume thereof are essential to enhance performance of an inverter for the eco-friendly vehicle. Therefore, methods for enhancing heat radiation efficient using unique cooling schemes for the power module have been proposed.

For example, for a double-sided power module heat generated from an upper portion of a chip is transferred to an upper metal substrate through an electrode made of metal materials such as copper Cu and copper molybdenum CuMo and thus is radiated. In other words, the upper metal substrate on a semiconductor device is electrically/thermally bonded using metal or an electrode (or spacer) plated with metal. The electrode is insufficient as a heat radiating material, thus causing the thermal resistance to increase. Further, insufficient radiation of heat may cause micro cracks in the reliability of a high temperature operation. In particular, the electrode is a factor of lowering thermal conductivity and/or electric conductivity.

The above information disclosed in this section is merely for enhancement of understanding of the background of the invention and therefore it may contain information that does not form the prior art that is already known in this country to a person of ordinary skill in the art.

### SUMMARY

The present invention provides a power semiconductor module with high reliability at a high temperature operation while improving heat radiating characteristics and a method for manufacturing the same. In one aspect, an exemplary embodiment of the present invention is directed to a power semiconductor module having thermal conductivity and/or electric conductivity and a method for manufacturing the same. In another exemplary embodiment a power semiconductor module may be reduced in volume by removing a metal electrode (e.g., spacer) and a method for manufacturing the same.

In one aspect, the power semiconductor module may include a lower substrate and a first electronic device that may be bonded to a surface of the lower substrate. A lead frame may have a first side surface bonded to a surface of the first electronic device by a first adhesive and a second electronic device that may be bonded to a second side surface of the lead frame by the first adhesive. An upper substrate may be bonded to a surface of the second electronic device. The upper substrate and the lower substrate may be a conductive heat radiating processing substrate into which an insulator may be inserted to emit heat. The lead frame may be positioned at a center between the upper substrate and the lower substrate in a form in which the upper substrate and the lower substrate adjacent to each other to provide a heat radiating path.

The first electronic device and the second electronic device may be different. The first electronic device and the second electronic device may be a power semiconductor device or a polar semiconductor device. The power semiconductor device may be any one of an insulated gate transistor (IGBT), a bipolar, and a power metal oxide silicon field effect transistor (MOSFET). The polar semiconductor device may be a diode.

The lead frame may have an upper side surface provided with the second electronic device and a lower side surface, adjacent to the upper side surface, provided with the first electronic device to cool a plurality of sides. The lead frame may be partially refracted to be bonded and fixed to an inner side surface of the first substrate or the second substrate. The first electronic device and the second electronic device may be configured in a parallel circuit with each other. The first electronic device and the lower substrate may be bonded to each other by a second adhesive, the second electronic device and the upper substrate may be bonded to each other by the second adhesive, and the first adhesive and the second adhesive may be a solder.

Another exemplary embodiment of the present invention provides a method for manufacturing a power semiconductor module, that may include preparing a lower substrate and an upper substrate, bonding a first electronic device to a surface of the lower substrate and bonding a second electronic device to a surface of the upper substrate; and bonding a first side surface of a lead frame to the surface of the first electronic device by a first adhesive and bonding a second surface of the lead frame to one side surface of the second electronic device by the first adhesive. The bonding of the device may include bonding the first electronic device to the lower substrate by a second adhesive and bonding the second electronic device to the upper substrate by the second adhesive.

### BRIEF DESCRIPTION OF THE DRAWINGS

The above and other objects, features and advantages of the present invention will be more clearly understood from the following detailed description when taken in conjunction with the accompanying drawings, in which:

FIG. 1 is an exemplary conceptual cross-sectional view of a power semiconductor module according to an exemplary embodiment of the present invention;

FIG. 2 is an exemplary perspective view illustrating a lead frame in the power semiconductor illustrated in FIG. 1 is assembled with a lower substrate according to an exemplary embodiment of the present invention;

FIG. 3 is an exemplary process diagram illustrating a method for manufacturing a power semiconductor module according to an exemplary embodiment of the present invention;

FIG. 4A is an exemplary cross-sectional view illustrating a structure of an upper substrate or a lower substrate illustrated in FIG. 3 according to an exemplary embodiment of the present invention;

FIG. 4B is an exemplary cross-sectional view illustrating a concept of forming a bonding layer for bonding an electronic device to the upper substrate or the lower substrate illustrated in FIG. 4A according to an exemplary embodiment of the present invention;

FIG. 4C is an exemplary cross-sectional view illustrating a process of bonding the electronic device to the bonding layer illustrated in FIG. 4B according to an exemplary embodiment of the present invention;

FIG. 4D is an exemplary cross-sectional view illustrating a process of the bonding layer to an upper end surface of the electronic device illustrated in FIG. 4C according to an exemplary embodiment of the present invention; and

FIG. 4E is an exemplary cross-sectional view illustrating a concept of bonding a lead frame to the bonding layer illustrated in FIG. 4D according to an exemplary embodiment of the present invention.

### DETAILED DESCRIPTION

Hereinafter, exemplary embodiments of the present invention will be described in detail with reference to the accompanying drawings so that those skilled in the art may easily practice the present invention. However, the present invention may be modified in various different ways and is not limited to the exemplary embodiments provided in the present description. In the accompanying drawings, portions unrelated to the description will be omitted in order to obviously describe the present invention, and similar reference numerals will be used to describe similar portions throughout the present specification.

In the drawings, the thickness of layers and regions are exaggerated for clarity. Like reference numerals designate like elements throughout the specification. It will be understood that when an element such as a layer, film, region, or substrate is referred to as being “on” another element, it can be directly on the other element or intervening elements may also be present.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

In contrast, when an element is referred to as being “directly on” another element, there are no intervening elements present. Further, “wholly” forming any element on another element means that any element is formed on the whole surface (or front surface) of another element and that any element is not formed on a portion of edges.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

Hereinafter, a power semiconductor module and a method for manufacturing the same according to an exemplary embodiment of the present invention will be described in detail with reference to the accompanying drawings.

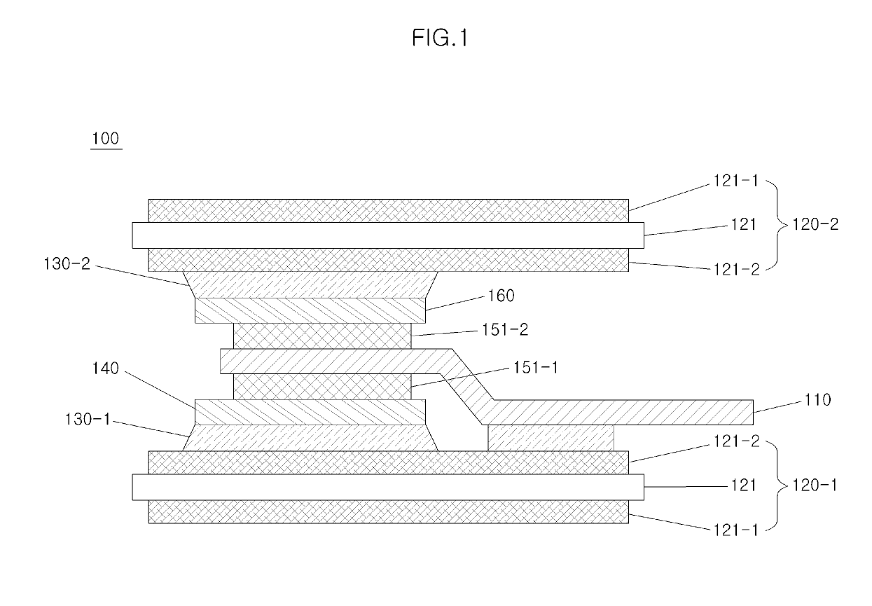

FIG. 1 is an exemplary conceptual cross-sectional view of a power semiconductor module according to an exemplary embodiment of the present invention. Referring to FIG. 1, a power semiconductor module 100 may include a lower substrate 120-1, a first electronic device 140 that may be to a surface of the lower substrate 120-1, an upper substrate 120-2, a second electronic device 160 that may be bonded to a surface of the upper substrate 120-2, and a lead frame 110 that may be bonded to the surfaces of the first electronic device 140 and the second electronic device 160, etc.

In particular, the upper substrate 120-2 and/or the lower substrate 120-1, may include a conductive heat radiating processing substrate into which an insulator may be inserted to emit heat. The upper and lower substrates 120-1 and 120-2 may to include an insulating layer 121 and a lower copper plate 121-1 and an upper copper plate 121-2 which are copper-foiled on both surfaces of the ceramic 121. In other words, the insulating layer 121 may be made of a ceramic material, for example, a ceramic material having aluminum oxide Al₂O₃ of about 96%. The copper plates 121-1 and 121-2 which are a copper layer may be set to be a thickness of about 300 μm.

In particular, as the conductive heat radiating substrate, a directed copper bonded (DCB) substrate, etc., may be used. The DCB substrate has excellent heat radiating characteristics. Further, the lower and upper copper plates 121-1 and 121-2 may be made of conductive aluminum, etc., in addition to copper. The lead frame 110 may be positioned at a substantial center in a form of the upper substrate 120-2 and the lower substrate 120-1 adjacent to each other to form a heat radiating path. Therefore, a path may be formed between the upper substrate 120-2 and the lower substrate 120-1. The path may be used as an electrode and/or the heat radiating path.

In particular, an upper end surface of the lead frame 110 may be bonded to the second electronic device 160 by an adhesive and a lower end surface thereof may be bonded to the first electronic device 140. In other words, the first and second electronic devices 140 and 160 may be bonded to the lead frame 110 through first and second frame bonding layers 151-1 and 151-2. Further, the first electronic device 140 and the lower substrate 120-1 may be bonded to each other in advance by a first device bonding layer 130-1. Further, the second electronic device 160 and the upper substrate 120-2 may be bonded to each other by a second device bonding layer 130-2. The frame bonding layers 151-1 and 151-2 and/or the device bonding layers 130-1 and 130-2 may use the same adhesive or different adhesives. The adhesive may be a solder and may be materials having different melting points.

Further, the lead frame 110 may be partially refracted to be bonded and fixed to an inner side surface of the first substrate 120-1. Further, as illustrated in FIG. 1, the lead frame 110 may be bonded to the inner side surface of the first substrate 120-1 but may be bonded and fixed to an inner side surface of the second substrate 120-2. For example, the first electronic device 140 and the second electronic device 160, may include different electronic devices. In other words, the first electronic device 140 and the second electronic device 160 are disposed on a single electrode substrate may be separately disposed at the upper and lower portion, thereby reducing a size of the power semiconductor module 100.

Referring to FIG. 1, the first electronic device may be a power semiconductor device and the second electronic device may be a polar semiconductor device. The power semiconductor device may include an insulated gate transistor (IGBT), a bipolar, and a power metal oxide silicon field effect transistor (MOSFET). In particular, the power MOSFET may perform a high voltage, high current operation and may have a double-diffused metal oxide semiconductor (DMOS) structure unlike a general MOSFET. Further, the polar semiconductor device may be a diode. The diode may include a zener diode, a tunnel diode, a schottky diode, etc. The first electronic device 140 and the second electronic device 160 may be configured in a parallel circuit with each other, thereby minimizing a space of the power semiconductor module 100. In other words, the first and second electronic devices 140 and 160 may be disposed using a minimum space. Further, the first electronic device 140 and/or the second electronic device 160 may have a chip form.

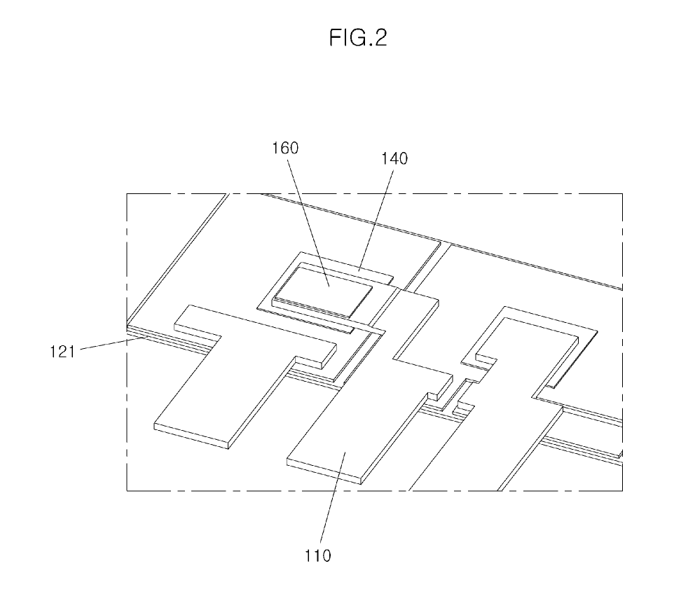

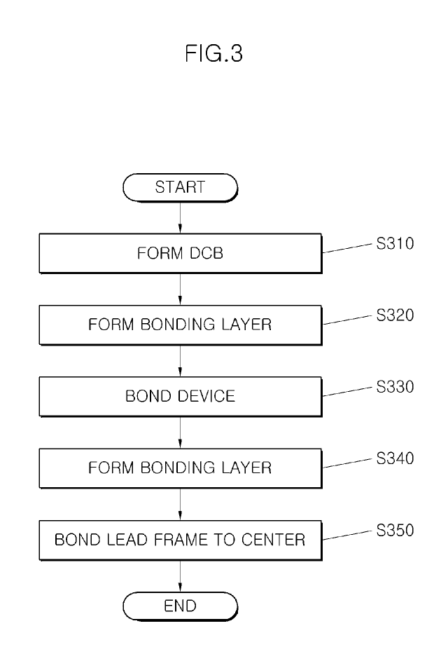

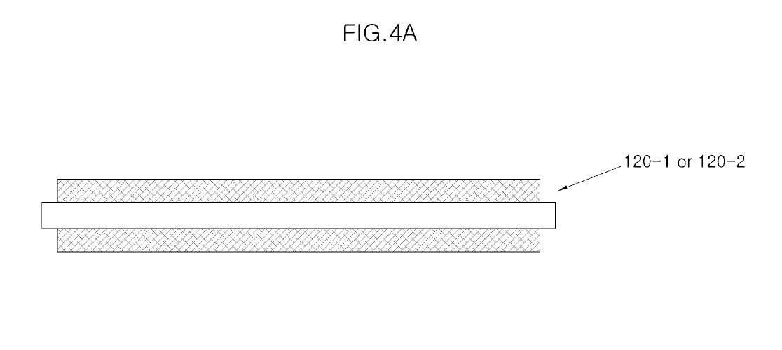

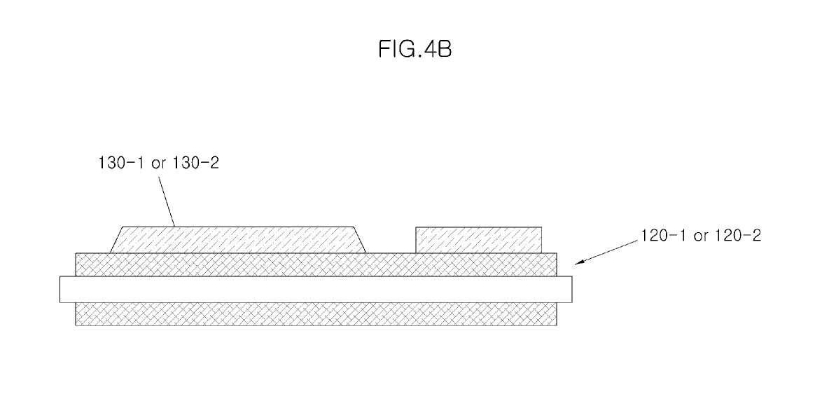

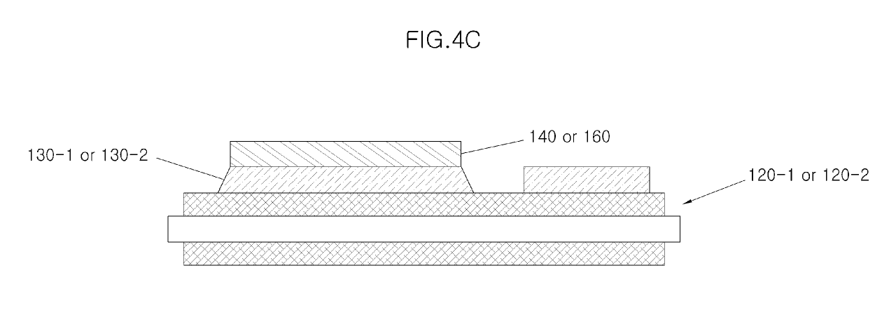

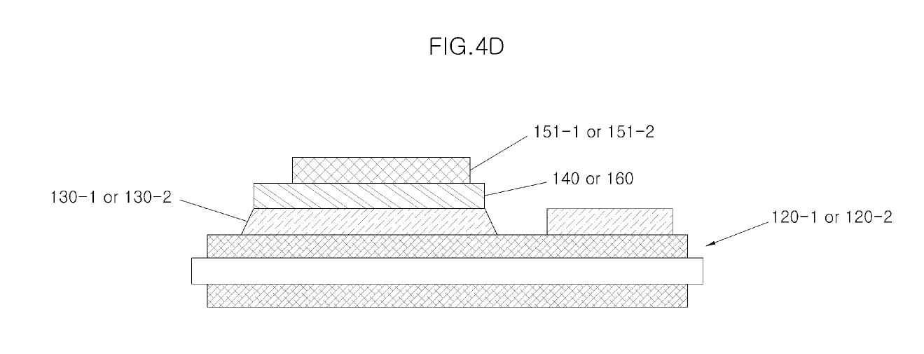

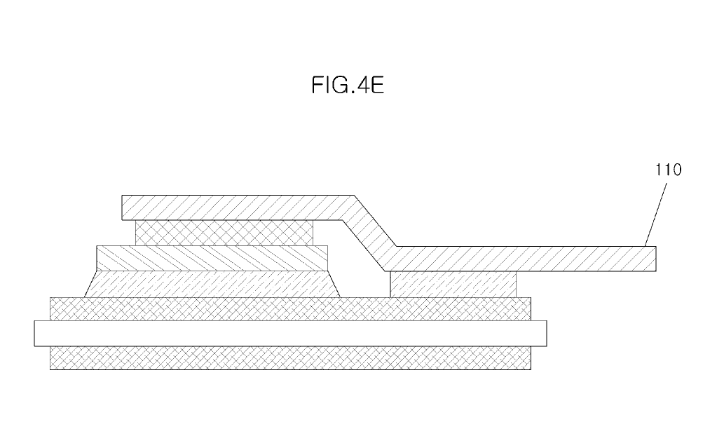

FIG. 2 is an exemplary perspective view illustrating a lead frame in the power semiconductor illustrated in FIG. 1 is assembled with a lower substrate accordingly to an exemplary embodiment. FIG. 3 is an exemplary process diagram illustrating a method for manufacturing a power semiconductor module according to an exemplary embodiment of the present invention. Further, FIG. 4A is an exemplary cross-sectional view illustrating a structure of the upper substrate 120-2 or the lower substrate 120-1 illustrated in FIG. 3. FIG. 4B is an exemplary cross-sectional view illustrating a forming the bonding layer 130-1 or 130-2 for bonding the electronic device to the upper substrate 120-2 or the lower substrate 120-1 illustrated in FIG. 4A. Further, FIG. 4C is an exemplary cross-sectional view illustrating a process of forming the electronic device 140 or 160 to the bonding layer 130-1 or 130-2 illustrated in FIG. 4B. FIG. 4D is an exemplary cross-section view illustrating a process of forming the bonding layer 151-1 or 151-2 to the upper end surface of the electronic device 140 or 160 illustrated in FIG. 4C. Further, FIG. 4E is an exemplary cross-sectional view illustrating a concept of bonding the lead frame 110 to the bonding layer 151-1 or 151-2 illustrated in FIG. 4D.

Referring to FIGS. 3 and 4A to 4E, the lower substrate 120-1 and the upper substrate 120-2 may be prepared S310 as shown in FIG. 4A. The first and second device bonding layers 130-1 and 130-2 may each be formed on the lower substrate 120-1 and the upper substrate 120-2 S320 as illustrated in FIG. 4B. The first and second electronic devices 140 and 160 may be bonded to the device bonding layers 130-1 and 130-2 S330 as shown in FIG. 4C. Further, the first and second frame bonding layers 151-1 and 151-2 may each be bonded to the surfaces of the first and second electronic devices 140 and 160 S340. Finally, the lead frame 110 may be bonded to the first and second frame bonding layers 151-1 and 151-2 S350.

FIG. 4E representatively illustrates that the lead frame 110 may be bonded to the first and second frame bonding layers 151-1 and 151-2. Additionally, the lead frame 110 may be bonded to the bonding layer of the adjacent (e.g., opposite) side as shown in FIG. 1. The exemplary embodiment of the present invention describes that the first frame bonding layer 151-1 and the second frame bonding layer 151-2 may be bonded to the lead frame 110, however, the first frame bonding layer 151-1 and the second frame bonding layer 151-2 may be bonded to the lead frame 110 at a time difference. Further, other processes may be simultaneously performed or may be performed at different times.

According to the exemplary embodiments of the present invention, cost savings, increasing the yield, and/or stabilizing the assembling may be accomplished by removing the electrode (e.g., spacer) and may contribute to the reduction in yield and/or the increase in price. Further, the size of the power semiconductor module may be reduced by separately disposing the power semiconductor and the diode, which are typically disposed on the single electrode substrate, at the upper and lower portions. The process simplification and/or save costs may be achieved by removing the wire bonding process between the lead frame and the substrate. Further, the thermal resistance may be reduced by removing the electrode and may improve the heat radiating performance by additionally generating the heat radiating path through the lead frame. The delamination between the electrode (e.g., spacer) and the electrode substrate may be prevented and the relevant reliability problem.

The foregoing exemplary embodiments are only examples to allow a person having ordinary skill in the art to which the present invention pertains to easily practice the present invention. Accordingly, the present invention is not limited to the foregoing exemplary embodiments and the accompanying drawings, and therefore, a scope of the present invention is not limited to the foregoing exemplary embodiments. Accordingly, it will be apparent to those skilled in the art that substitutions, modifications and variations can be made without departing from the spirit and scope of the invention as defined by the appended claims and can also belong to the scope of the present invention.

What is claimed is:

1. A power semiconductor module, comprising:
a lower substrate;
a first electronic device bonded to a surface of the lower substrate;
a lead frame having a first side surface bonded to a surface of the first electronic device by a first adhesive;
a second electronic device bonded to a second side surface of the lead frame by the first adhesive; and
an upper substrate bonded to a surface of the second electronic device.

2. The power semiconductor module of claim 1, wherein the upper substrate and the lower substrate are each a conductive heat radiating processing substrate having an insulator disposed therein to emit heat.

3. The power semiconductor module of claim 1, wherein the lead frame is positioned at a center between the upper substrate and the lower substrate with the upper substrate and the lower substrate positioned adjacent to each other to provide a heat radiating path.

4. The power semiconductor module of claim 1, wherein the first electronic device and the second electronic device are different.

5. The power semiconductor module of claim 4, wherein the first electronic device and the second electronic device are each a power semiconductor device or a polar semiconductor device.

6. The power semiconductor module of claim 5, wherein the power semiconductor device is selected from a group consisting of an insulated gate transistor (IGBT), a bipolar, and a power metal oxide silicon field effect transistor (MOSFET), and the polar semiconductor device is a diode.

7. The power semiconductor module of claim 1, wherein the lead frame has an upper side surface provided with the second electronic device and a lower side surface, disposed adjacent to the upper side surface, provided with the first electronic device to cool a plurality of sides.

8. The power semiconductor module of claim 1, wherein the lead frame is partially refracted to be bonded and fixed to an inner side surface of the first substrate or the second substrate.

9. The power semiconductor module of claim 1, wherein the first electronic device and the second electronic device are in a parallel circuit with each other.

10. The power semiconductor module of claim 1, wherein the first electronic device and the lower substrate are bonded to each other by a second adhesive, the second electronic device and the upper substrate are bonded to each other by the second adhesive, and the first adhesive and the second adhesive are a solder.

11. A method for manufacturing a power semiconductor module, comprising:
preparing a lower substrate and an upper substrate;
bonding a first electronic device to a surface of the lower substrate and bonding a second electronic device to a surface of the upper substrate; and
bonding a first side surface of a lead frame to the surface of the first electronic device by a first adhesive and bonding a second surface of the lead frame to one side surface of the second electronic device by the first adhesive.

12. The method of claim 11, wherein the upper substrate and the lower substrate are a conductive heat radiating processing substrate into which an insulator is inserted to emit heat.

13. The method of claim 11, wherein the lead frame is positioned at a center between the upper substrate and the lower substrate having the upper substrate and the lower substrate positioned adjacent to each other to provide a heat radiating path.

14. The method of claim 11, wherein the first electronic device and the second electronic device are different.

15. The method of claim 14, wherein the first electronic device and the second electronic device are each a power semiconductor device or a polar semiconductor device.

16. The method of claim 15, wherein the power semiconductor device is selected from a group consisting of insulated gate transistor (IGBT), a bipolar, and a power metal oxide silicon field effect transistor (MOSFET), and the polar semiconductor device is a diode.

17. The method of claim 11, wherein the lead frame has an upper side surface provided with the second electronic device and a lower side surface, adjacent to the upper side surface, provided with the first electronic device to cool a plurality of sides.

18. The method of claim 11, wherein the lead frame is partially refracted to be bonded and fixed to an inner side surface of the first substrate or the second substrate.

19. The method of claim 11, wherein the first electronic device and the second electronic device are in a parallel circuit with each other.

20. The method of claim 11, wherein the bonding of the device includes:
bonding the first electronic device to the lower substrate by a second adhesive; and
bonding the second electronic device to the upper substrate by the second adhesive, wherein the first adhesive and the second adhesive are a solder.
